(19) United States
(12) Patent Application Publication
(10) Pub. No.: US 2026/0150239 A1
(43) Pub. Date: May 28, 2026

(54) COLD PLATE COOLING DEVICE

(71) Applicant: Delta Electronics, Inc., Taoyuan City (TW)

(72) Inventors: Ming-Kun Tsai, Taoyuan City (TW); Yin-Yuan Chen, Taoyuan City (TW); Shih-Kai Chien, Taoyuan City (TW); Ming-Tsung Lee, Taoyuan City (TW)

(21) Appl. No.: 19/177,636

(22) Filed: Apr. 14, 2025

Related U.S. Application Data
(60) Provisional application No. 63/718,798, filed on Nov. 11, 2024.

(30) Foreign Application Priority Data
Feb. 26, 2025 (CN) 202510215985.8

(51) Int. Cl. H05K 7/20

(52) U.S. Cl. CPC H05K 7/20272; H05K 7/20254; H05K 7/20336; H05K 7/20436; H05K 7/20509

(57) ABSTRACT

A cold plate cooling device is disclosed and includes a vapor chamber, a cooling chamber, an inlet, an outlet and a jet module. The vapor chamber includes a top portion and a bottom portion arranged opposite to each other, and thermally coupled to a heat source and plural heat sink fins. The cooling chamber is arranged on the top portion. The inlet and the outlet are in fluid communication with the cooling chamber, respectively. A coolant enters the cooling chamber through the inlet, exchanges heat with the heat sink fins in the cooling chamber, and then is discharged through the outlet. The jet module includes a through-hole arranged between the inlet and the cooling chamber. A total through-hole area of the through-hole is smaller than a total opening area of the inlet. Thereby, an impingement flow is generated toward the heat sink fins to dissipate heat from the vapor chamber.

### CROSS-REFERENCE TO RELATED APPLICATION

This application claims the benefit of U.S. Provisional Application No. 63/718,798 filed on Nov. 11, 2024, and entitled “COLD PLATE COOLING DEVICE”. This application claims priority to China Patent Application No. 202510215985.8, filed on Feb. 26, 2025. The entireties of the above-mentioned patent application are incorporated herein by reference for all purposes.

### FIELD OF THE INVENTION

The present disclosure relates to a heat dissipation device, and more particularly to a cold plate cooling device, which forms multiple impingement flows by setting a jet module for dissipating heat to the cold plate below, so that the heat dissipation efficiency of the vapor chamber is enhanced.

### BACKGROUND OF THE INVENTION

For current multi-chip packaging designs, multiple heat sources with different heating powers are generated inside a single package. However, corresponding to the multiple heat sources with different heating powers, a single heat dissipation module often leads to poor heat dissipation performance in local hot spot, and it will cause chip failure or reduce the efficiency. It further causes a loss in device performance.

Therefore, there is a need of providing a cold plate cooling device with a vapor chamber. With the contact between the vapor chamber and the chip package, the heat generated from different heat sources can be quickly absorbed and then diffused through the phase change of the vapor chamber. In addition, the upper part of the vapor chamber is a liquid cooling plate, and a jet mechanism is introduced between multiple inlets and multiple outlets to enhance the heat transfer of the coolant, so that the heat generated from different heat sources is taken away evenly by the coolant enhanced by the jet module.

### SUMMARY OF THE INVENTION

An object of the present disclosure is to provide a cold plate cooling device with a vapor chamber. The vapor chamber is in contact with the chip package, so that the heat generated from different heat sources is quickly absorbed and then diffused through the phase change of the vapor chamber. In addition, the upper part of the vapor chamber is a liquid cooling plate, and a jet mechanism is introduced between multiple inlets and multiple outlets to enhance the heat transfer of the coolant, so that the heat generated from different heat sources is taken away evenly by the coolant enhanced by the jet module.

Another object of the present disclosure is to provide a cold plate cooling device. A jet module is arranged between the inlet and the cooling chamber to form multiple impingement flows to dissipate heat from the cold plate below, so as to enhance the heat dissipation performance of the vapor chamber. The cooling chamber of the cold plate and vapor chamber are stacked up and down. The vapor chamber is thermally coupled to the chip package. Through the latent heat of phase change of the vapor chamber, the heat generated by the chip package can be absorbed and then diffused to the heat sink fins of the cold plate above. The heat sink fins are arranged in an open cooling chamber, and the coolant flows from the inlet to the outlet through the cooling chamber to take away the heat absorbed from the chip package. The jet module includes at least one through-hole of such as a partition plate disposed between the inlet and the cooling chamber. The partition plate further divides the cooling chamber into an upper and lower double-layer structure. The position of the through-hole is arranged and aligned correspondingly to the heat source. The coolant flowing through the inlet is transported from the upper buffer chamber to the lower cooling chamber through the through-hole on the partition plate. Since the total through-hole area of all through-holes on the partition plate is smaller than the total opening area of the inlet for the coolant, a jet effect can be created by the difference in the area ratio of the total opening area of the inlet to the total through-hole area of the through-holes. The coolant is evenly distributed through the through-holes and multi impingement flows are generated toward the plurality of heat sink fins in the lower cooling chamber for heat dissipation. Thereby, the heat dissipation performance of the vapor chamber for the chip package is enhanced. The numbers of inlets, through-holes and the outlets are adjustable according to the practical requirements and is not limited to one. The position of the through-hole on the partition plate can be adjusted to correspond to the position of the heat source and be misaligned from the inlet. The shape of the through-hole can be a circular aperture or an elongated aperture. Multiple outlets are disposed to reduce the pressure drop of the coolant flowing through the cooling chamber, so as to ensure that the jet module forms the impingement flow to improve the heat dissipation efficiency of the heat sink fins. On the other hand, the through-hole of the jet module and the inlet can be integrally formed into one piece and arranged above the heat source. By utilizing the difference in the ratio of the total opening area of the inlet and the total through-hole area of the through-hole, a jet structure is constructed to create a jet effect, so that the heat transfer effect of the heat sink fins to the vapor chamber is enhanced in an impingement-flow manner. The manner of constructing the jet structure adjacent to the inlet may be, for example, but not limited to, a step structure or a pipe with a gradually decreasing diameter. The number of the inlets integrated with the through-holes and the number of the outlets are adjustable according to the practical requirements. Furthermore, the pressure drop of the coolant in the cooling chamber can be controlled through the setting of the outlet. It also ensures that the jet module forms an impingement flow to improve the heat dissipation efficiency of the heat sink fins. The present disclosure includes the industrial applicability and the inventive steps.

In accordance with an aspect of the present disclosure, a cold plate cooling device is provided and includes a vapor chamber, a cooling chamber, an inlet, an outlet and a jet module. The vapor chamber includes a top portion and a bottom portion. The top portion and the bottom portion are arranged opposite to each other in a first direction, the bottom portion is thermally coupled to a heat source, and the top portion is thermally coupled to a plurality of heat sink fins. The cooling chamber is arranged on the top portion of the vapor chamber. The plurality of heat sink fins are accommodated in the cooling chamber. The inlet and the outlet are in fluid communication with the cooling chamber, respectively. A coolant enters the cooling chamber through the inlet, exchanges heat with the plurality of heat sink fins in the cooling chamber, and then is discharged through the outlet. The jet module includes at least one through-hole arranged between the inlet and the cooling chamber. The at least one through-hole has a total through-hole area, and the total through-hole area is smaller than a total opening area of the inlet. When the coolant flows through the at least one through-hole, an impingement flow is generated toward the plurality of heat sink fins to dissipate heat from the vapor chamber.

In an embodiment, the at least one through-hole of the jet module is spatially corresponding to the heat source, and the at least one through-hole of the jet module is included in a projection region of the heat source in view of the first direction.

In an embodiment, the heat source includes at least one pair of heat sources, and the at least one pair of heat sources are arranged along a second direction and thermally coupled to the bottom portion of the vapor chamber, wherein the second direction is perpendicular to the first direction.

In an embodiment, the cold plate cooling device further includes a partition plate stacked along the first direction and arranged between the top portion of the vapor chamber and the inlet, wherein the jet module is disposed on the partition plate.

In an embodiment, the at least one through-hole and the inlet are misaligned in view of the first direction.

In an embodiment, the at least one through-hole includes at least one pair of through-holes, which are arranged along a second direction and symmetrically disposed on two opposite sides of the inlet, wherein the second direction is perpendicular to the first direction.

In an embodiment, the at least one through-hole includes at least one pair of circular apertures, which are located on two opposite sides of the inlet, respectively.

In an embodiment, the at least one through-hole includes at least one pair of elongated apertures extended along a second direction and located at two opposite sides of the inlet, respectively, wherein the second direction is perpendicular to the first direction.

In an embodiment, the at least one through-hole is a circular aperture or an elongated aperture extended along a second direction, wherein the second direction is perpendicular to the first direction.

In an embodiment, a total opening area of the outlet is greater than the total through-hole area of the at least one through-hole.

In an embodiment, a buffer chamber is formed between the partition plate and the inlet, and the outlet includes at least one pair of outlets, and the at least one pair of outlets are located at two opposite sides of the buffer chamber.

In an embodiment, the at least one through-hole and the inlet are integrally formed and correspondingly connected.

In an embodiment, the inlet is connected to the at least one through-hole of the jet module along the first direction to form a step structure.

In an embodiment, the inlet is connected to the at least one through-hole with a gradually decreasing diameter along the first direction.

In an embodiment, the inlet is included in a projection region of the heat source in view of the first direction.

In an embodiment, the heat source includes at least one pair of heat sources, and the at least one pair of heat sources are arranged along a second direction and thermally coupled to the bottom portion of the vapor chamber, wherein the second direction is perpendicular to the first direction.

In an embodiment, the inlet includes a plurality of inlets, the outlet comprises a plurality of outlets, and the number of the plurality of outlets is greater than or equal to the number of the plurality of inlets.

In an embodiment, the inlet includes a plurality of inlets, the outlet includes a plurality of outlets, and a total opening area of the plurality of outlets is greater than or equal to the total opening area of the plurality of inlets.

In an embodiment, the coolant flows through the inlet and the outlet parallel to the first direction.

In an embodiment, the heat source includes a plurality of heat-generating chips packaged into one piece, and directly thermally coupled to the bottom portion of the vapor chamber.

In an embodiment, the top portion of the vapor chamber is integrally formed with the plurality of heat sink fins, and the plurality of heat sink fins are protruded from bottom to top.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a schematic structural view illustrating a cold plate cooling device according to a first embodiment of the present disclosure;

FIG. 2 is a top view illustrating the cold plate cooling device according to the first embodiment of the present disclosure;

FIG. 3 is a top view illustrating a cold plate cooling device according to a second embodiment of the present disclosure;

FIG. 4 is a top view illustrating a cold plate cooling device according to a third embodiment of the present disclosure;

FIG. 5 is a top view illustrating a cold plate cooling device according to a fourth embodiment of the present disclosure;

FIG. 6 is a schematic structural view illustrating a cold plate cooling device according to a fifth embodiment of the present disclosure;

FIG. 7 is a top view illustrating the cold plate cooling device according to the fifth embodiment of the present disclosure; and

FIG. 8 to FIG. 11 show different exemplary structures having the jet module and the inlet integrally formed according to present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “top,” “bottom,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

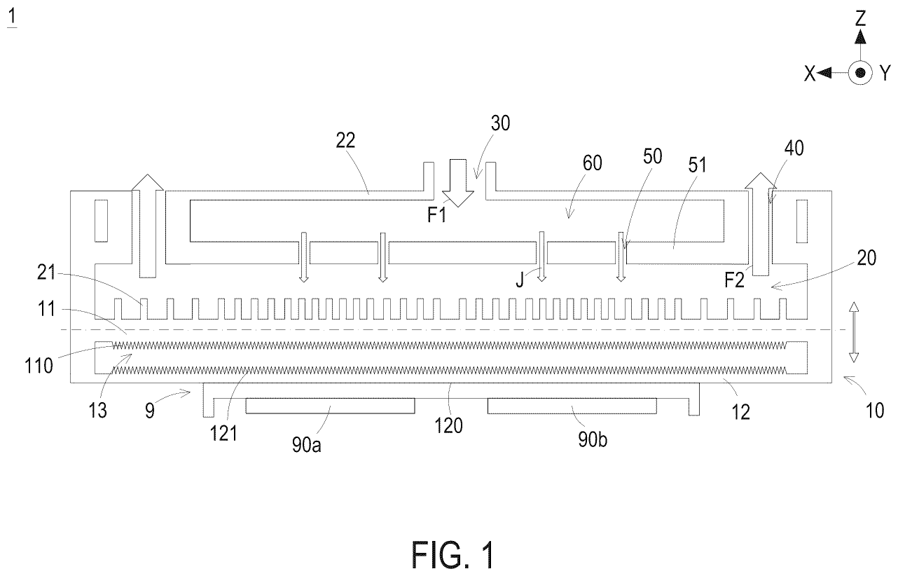

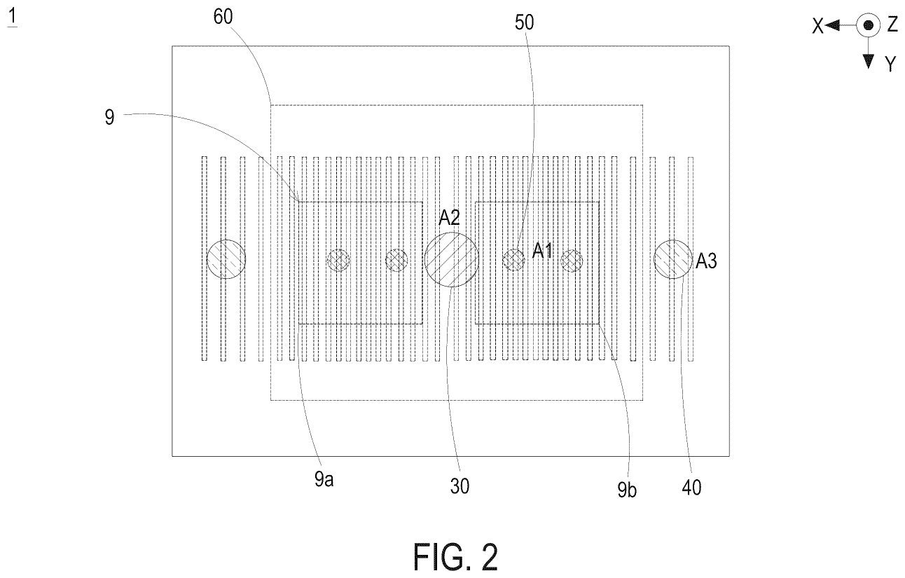

FIG. 1 is a schematic structural view illustrating a cold plate cooling device according to a first embodiment of the present disclosure. FIG. 2 is a top view illustrating the cold plate cooling device according to the first embodiment of the present disclosure. Please refer to FIG. 1 and FIG. 2. The present disclosure provides a cold plate cooling device 1, which includes a vapor chamber 10, a cooling chamber 20, an inlet 30, an outlet 40 and a jet module. The vapor chamber 10 includes a top portion 11 and a bottom portion 12. The top portion 11 and the bottom portion 12 are disposed and arranged opposite to each other in a first direction (i.e., the reverse Z-axis direction). In the embodiment, the bottom portion 12 of the vapor chamber 10 is thermally coupled to a heat source 9, and the top portion 11 of the vapor chamber 10 is thermally coupled to a plurality of heat sink fins 21. The cooling chamber 20 is arranged on the top portion 11 of the vapor chamber 10. The plurality of heat sink fins 21 are accommodated in the cooling chamber 20. In an embodiment, the sidewalls of the cooling chamber 20 and the heat sink fins 21 are protruded upward from the top portion 11 of the vapor chamber 10, and integrally formed into one-piece structure by metal materials, and then a top cover 22 covers thereon to form the space of the cooling chamber 20. The inlet and the outlet are passing through the top cover 22 and in fluid communication with the cooling chamber 20, respectively. A coolant (not shown) enters the cooling chamber 20 through the inlet 30, exchanges heat with the plurality of heat sink fins 21 in the cooling chamber 20, and then is discharged through the outlet 40. Notably, the jet module includes at least one through-hole 50 arranged between the inlet 30 and the cooling chamber 20. The at least one through-hole 50 has a total through-hole area A1, and the total through-hole area A1 is smaller than a total opening area A2 of the inlet 30. Thereby, when the coolant flows through the at least one through-hole 50, an impingement flow J is generated toward the plurality of heat sink fins 21 to dissipate heat from the vapor chamber 10 above, so that the heat dissipation performance of the vapor chamber 10 is enhanced.

In the embodiment, the cold plate cooling device 1 further includes a partition plate 51 stacked along the first direction (i.e., the reverse Z-axis direction) and arranged between the top portion 11 of the vapor chamber 10 and the inlet 30. The jet module is disposed on the partition plate 51. A buffer chamber 60 is formed between the partition plate 51 and the inlet 30. In the embodiment, the heat source 9 includes at least one pair of heat sources 90a, 90b, which are arranged along the second direction (i.e., the X-axis direction) and thermally coupled to the bottom portion 12 of the vapor chamber 10. The second direction is perpendicular to the first direction. Preferably but not exclusively, each heat source 90a, 90b is a heat-generating chip. The plurality of heat sources 90a, 90b (i.e., the plurality of heat-generating chips) are further packaged into one piece and directly thermally coupled to the heat dissipation surface 120 of the bottom portion 12 of the vapor chamber 10. Certainly, the present disclosure is not limited thereto. Preferably but not exclusively, in the embodiment, the top portion 11 of the vapor chamber 10 is integrally formed with the plurality of heat sink fins 21, and the plurality of heat sink fins 21 are protruded from bottom to top. It should be noted that the vapor chamber 10 includes a closed chamber 13, and a two-phase working fluid (not shown) is sealed inside the closed chamber 13. The top portion 11 and the bottom portion 12 further includes microstructures 110, 121 in the relatively closed chamber 13, respectively. The heat generated from the plurality of heat sources 90a, 90b below the heat dissipation surface 120 is quickly absorbed and diffused through the latent heat of the phase change of the working fluid, and then dissipated from the heat sink fins 21 above the top portion 11. The number and the shape of the heat sources 90a, 90b are merely examples and can be adjusted according to the practical requirements, which must be explained first.

In the embodiment, the at least one through-hole 50 on the partition plate 51 and the inlet 30 above the buffer chamber 60 are misaligned in view of the first direction (i.e., the reverse Z-axis direction). The outlet 40 includes at least one pair of outlets 40, and the at least one pair of outlets 40 are located at two opposite sides of the buffer chamber 60. In the embodiment, the coolant enters the buffer chamber 60 through the inlet 30 in the first flow direction F1. Since the total through-hole area A1 of all through-holes 50 is smaller than the total opening area A2 of the inlet 30, the difference in area ratio between the total through-hole area A1 and the total opening area A2 can create a jet effect. The pressure drop of the coolant in the buffer chamber 60 is increased through the through-holes 50, and a plurality of impingement flows J are generated toward the heat sink fins 21 below directly. Thereby, the heat dissipation performance of the vapor chamber 10 for the plurality of heat sources 90a, 90b is further enhanced. After completing heat exchange with the plurality of heat sink fins 21 in the cooling chamber 20, the coolant is discharged through the outlet 40 in the second flow direction F2. Thus, the heat is continuously and stably removed from the cold plate cooling device 1.

In the embodiment, the cold plate cooling device 1 includes an inlet 30 and two outlets 40. Certainly, the numbers of the inlets 30, the through-holes 50 and the outlet 40 are adjustable according to the practical requirements, and not limited to one. The coolant flows through the inlet 30 and the outlet 40 in a direction parallel to the first direction (i.e., the reverse Z-axis direction). In the embodiment, the positions of the through-holes 50 on the partition plate 51 are adjusted and corresponding to the positions of the heat sources 90a, 90b, and is misaligned from the inlet 30 in the first direction (i.e., the reverse Z-axis direction). In the embodiment, the at least one through-hole 50 include a pair of through-holes 50. The pair of through-holes 50 are circular apertures, arranged along the second direction (i.e., the X-axis direction), and symmetrically disposed on two opposite sides of the inlet 30. Each heat source 90a, 90b is spatially corresponding to two through-holes 50 with two impingement flows J. The coolant in the buffer chamber 60 is evenly distributed and transported downward through the four through-holes 50, so that four impingement flows J are formed to directly correspond to the heat sink fins 21 and the two heat sources 90a, 90b stacked below in the first direction (i.e., the reverse Z-axis direction). It helps the vapor chamber 10 to quickly absorb the heat generated from the heat sources 90a and 90b through the latent heat of phase change and diffuse the heat to the heat sink fins 21 of the upper cold plate for dissipation.

Moreover, notably, in the embodiment, the numbers and the shapes of the inlet 30 and the outlet 40 are not limited to be the same. Preferably but not exclusively, the total opening area A3 of the plurality of outlets 40 is greater than or equal to the total opening area A2 of the plurality of inlets. In other words, the total through-hole area A1 of all the through-holes 50 is also smaller than the total opening area A3 of the outlets 40. Since a larger total opening area A3 is further provided by the multiple outlets 40, the pressure drop of the coolant flowing through the cooling chamber 20 is further reduced. It is ensured that the jet module forms the impingement flows J to more effectively exert the heat dissipation performance on the heat sink fins 21. Certainly, the present disclosure is not limited thereto.

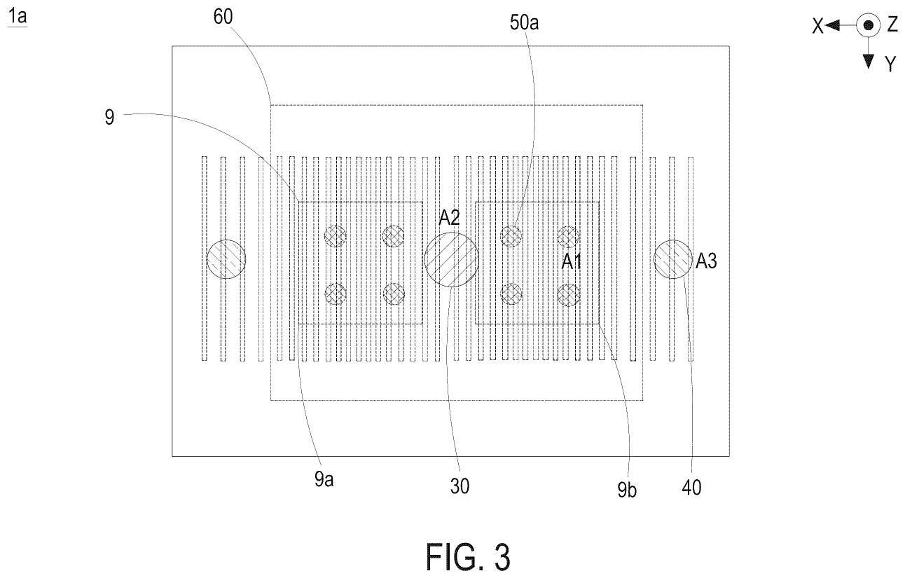

FIG. 3 is a top view illustrating a cold plate cooling device according to a second embodiment of the present disclosure. In the embodiment, the structures, elements and functions of the cold plate cooling device 1a are similar to those of the cold plate cooling device 1of FIG. 1 and FIG. 2, and are not redundantly described herein. Please refer to FIG. 1 and FIG. 3. In the embodiment, the heat source 9 includes a pair of heat sources 90a, 90b. Preferably but not exclusively, each of the heat sources 90a, 90b is a square heat-generating chip and integrally packaged into one piece. In the embodiment, the partition plate 51 includes eight through-holes 50a, corresponding to the positions of the two heat sources 90a, 90b, respectively, and misaligned to the inlet 30 in the first direction (i.e., the reverse Z-axis direction). Each through-hole 50a is a circular aperture with the same structure. Each heat source 90a, 90b is spatially corresponding to four corresponding through-holes 50a, forming a square array and arranged equidistantly along the X-axis and the Y-axis. The eight through-holes 50a are included in a projection region of the corresponding heat sources 90a, 90b in view of the first direction (i.e., the reverse Z-axis direction), respectively. It helps the coolant in the buffer chamber 60 to be evenly distributed and transported downward through the eight through-holes 50a. In that, eight impingement flows J are formed to directly correspond to the heat sink fins 21 and the two heat sources 90a, 90b stacked below in the first direction (i.e., the reverse Z-axis direction). The coolant enters the buffer chamber 60 through the inlet 30 in the first flow direction F1. Since the total through-hole area A1 of the eight through-holes 50a is smaller than the total opening area A2 of the inlet 30, the difference in area ratio between the total through-hole area A1 and the total opening area A2 can create a jet effect. The coolant in the buffer chamber 60 increases the pressure drop and flows through the through-holes 50a, and the eight impingement flows J are generated to flow toward the plurality of heat sink fins 21 below directly, so that the heat dissipation performance of the vapor chamber 10 for the two heat sources 90ac 90b is enhanced. After completing heat exchange with the plurality of heat sink fins 21 in the cooling chamber 20, the coolant is discharged through the outlet 40 in the second flow direction F2. Thus, the heat is continuously and stably removed from the cold plate cooling device 1a.

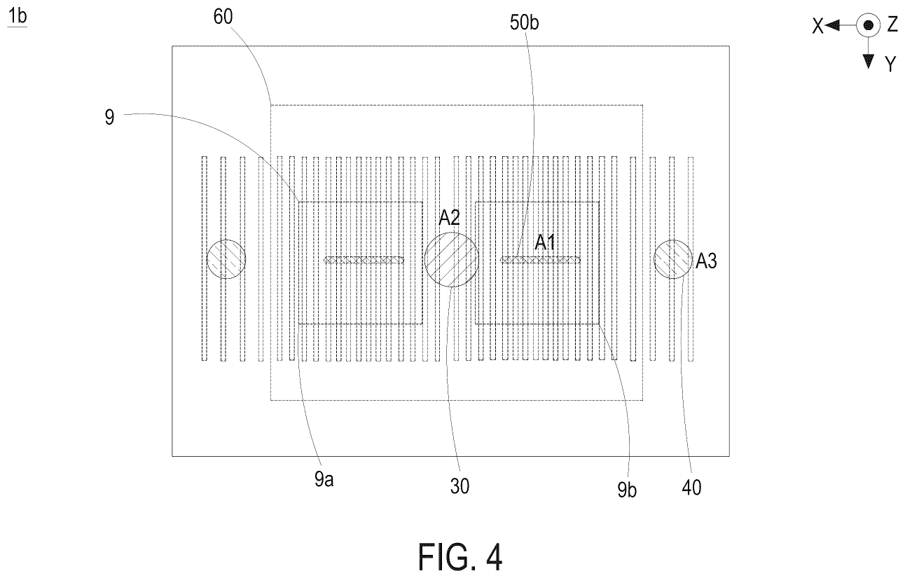

FIG. 4 is a top view illustrating a cold plate cooling device according to a third embodiment of the present disclosure. In the embodiment, the structures, elements and functions of the cold plate cooling device 1b are similar to those of the cold plate cooling device 1 of FIG. 1 and FIG. 2, and are not redundantly described herein. Please refer to FIG. 1 and FIG. 4. In the embodiment, the heat source 9 includes a pair of heat sources 90a, 90b. Preferably but not exclusively, each of the heat sources 90a, 90b is a square heat-generating chip and integrally packaged into one piece. In the embodiment, the partition plate 51 includes two through-holes 50b, corresponding to the positions of the two heat sources 90a, 90b, respectively, and misaligned to the inlet 30 in the first direction (i.e., the reverse Z-axis direction). Each through-hole 50b is an elongated aperture with the same structure extend along the second direction (i.e., the X-axis direction) and arranged in pairs at the opposite left and right sides of the inlet 30. Each heat source 90a, 90b is spatially corresponding to one corresponding through-hole 50b. The two through-holes 50b are included in a projection region of the corresponding heat sources 90a, 90b in view of the first direction (i.e., the reverse Z-axis direction), respectively. It helps the coolant in the buffer chamber 60 to be evenly distributed and transported downward through the two through-holes 50b. In that, two impingement flows J are formed to directly correspond to the heat sink fins 21 and the two heat sources 90a, 90b stacked below in the first direction (i.e., the reverse Z-axis direction). The coolant enters the buffer chamber 60 through the inlet 30 in the first flow direction F1. Since the total through-hole area A1 of the two through-holes 50b is smaller than the total opening area A2 of the inlet 30, the difference in area ratio between the total through-hole area A1 and the total opening area A2 can create a jet effect. The coolant in the buffer chamber 60 increases the pressure drop and flows through the through-holes 50b, and the two impingement flows J are formed and directly transported to the heat sink fins 21 below, so that the heat dissipation performance of the vapor chamber 10 for the two heat sources 90a, 90b is enhanced. After completing heat exchange with the plurality of heat sink fins 21 in the cooling chamber 20, the coolant is discharged through the outlet 40 in the second flow direction F2. Thus, the heat is continuously and stably removed from the cold plate cooling device 1b.

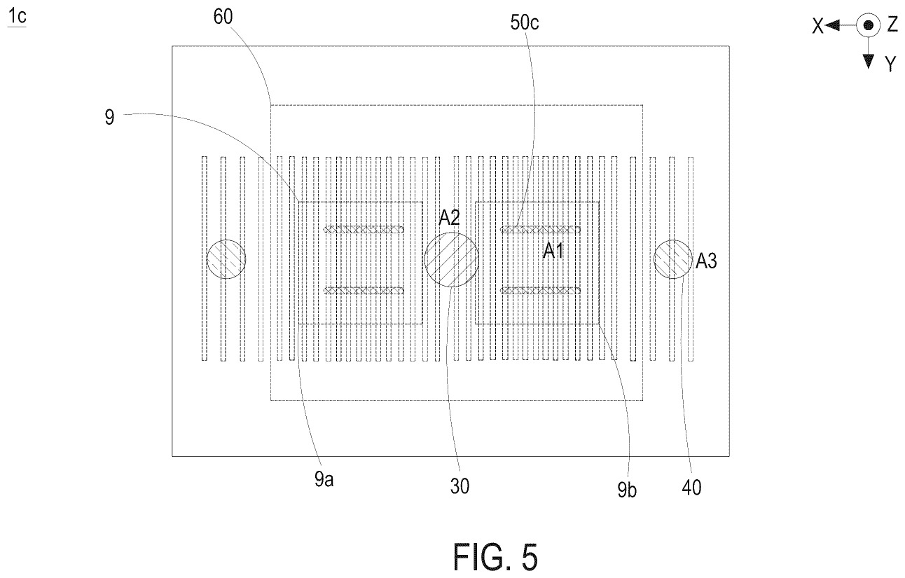

FIG. 5 is a top view illustrating a cold plate cooling device according to a fourth embodiment of the present disclosure. In the embodiment, the structures, elements and functions of the cold plate cooling device 1c are similar to those of the cold plate cooling device 1 of FIG. 1 and FIG. 2, and are not redundantly described herein. Please refer to FIG. 1 and FIG. 5. In the embodiment, the heat source 9 includes a pair of heat sources 90a, 90b. Preferably but not exclusively, each of the heat sources 90a, 90b is a square heat-generating chip and integrally packaged into one piece. In the embodiment, the partition plate 51 includes four through-holes 50c, corresponding to the positions of the two heat sources 90a, 90b, respectively, and misaligned to the inlet 30 in the first direction (i.e., the reverse Z-axis direction). Each through-hole 50c is an elongated aperture with the same structure extend along the second direction (i.e., the X-axis direction). Moreover, the four through-holes 50c are arranged in pairs at the opposite left and right sides of the inlet 30. Each heat source 90a, 90b is spatially corresponding to two corresponding through-holes 50c parallel to the X-axis and arranged at equal intervals along the Y-axis. The four through-holes 50c are included in a projection region of the corresponding heat sources 90a, 90b in view of the first direction (i.e., the reverse Z-axis direction), respectively. It helps the coolant in the buffer chamber 60 to be evenly distributed and transported downward through the four through-holes 50c. In that, four impingement flows J are formed to directly correspond to the heat sink fins 21 and the two heat sources 90a, 90b stacked below in the first direction (i.e., the reverse Z-axis direction). The coolant enters the buffer chamber 60 through the inlet 30 in the first flow direction F1. Since the total through-hole area A1 of the four through-holes 50c is smaller than the total opening area A2 of the inlet 30, the difference in area ratio between the total through-hole area A1 and the total opening area A2 can create a jet effect. The coolant in the buffer chamber 60 increases the pressure drop and flows through the through-holes 50c, and the four impingement flows J are generated to flow toward the plurality of heat sink fins 21 below directly, so that the heat dissipation performance of the vapor chamber 10 for the two heat sources 90a, 90b is enhanced. After completing heat exchange with the plurality of heat sink fins 21 in the cooling chamber 20, the coolant is discharged through the outlet 40 in the second flow direction F2. Thus, the heat is continuously and stably removed from the cold plate cooling device 1c.

Notably, in the aforementioned embodiments, the through-holes 50, 50a, 50b, 50c of the jet module can be adjusted in size, position and shape corresponding to the heat sources 90a, 90b. The jet effect can be achieved by maintaining the total through-hole area A1 of the through-holes 50, 50a, 50b, 50c smaller than the total opening area A2 of the inlet 30. Thereby, the required impingement flows J are formed and directly guided to the heat sink fins 21 below, so that the heat dissipation efficiency of the vapor chamber 10 for the two heat sources 90a, 90b is enhanced. Certainly, the through-holes 50, 50a, 50b, 50c of the jet module on the partition plate 51 are adjustable according to the practical requirements. The present disclosure is not limited thereto and not redundantly described herein.

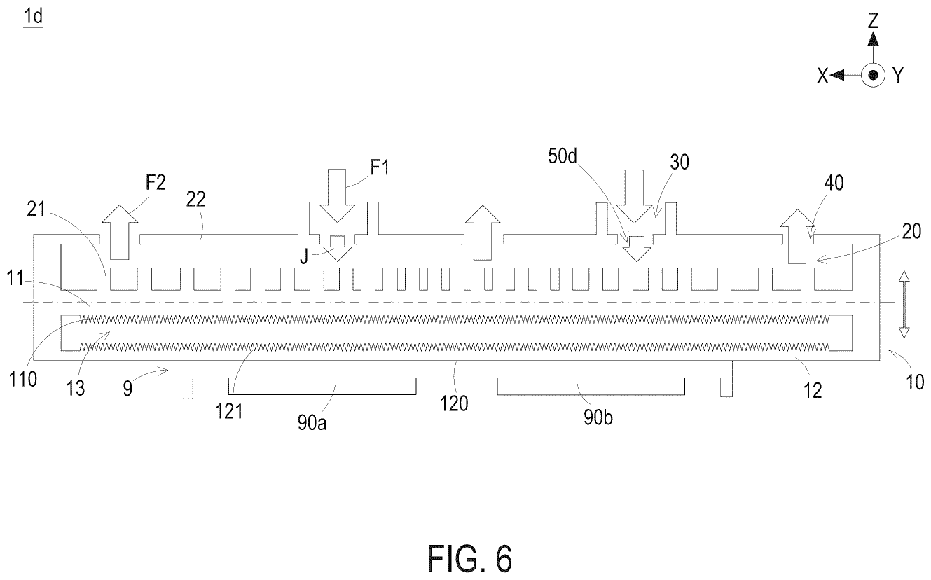

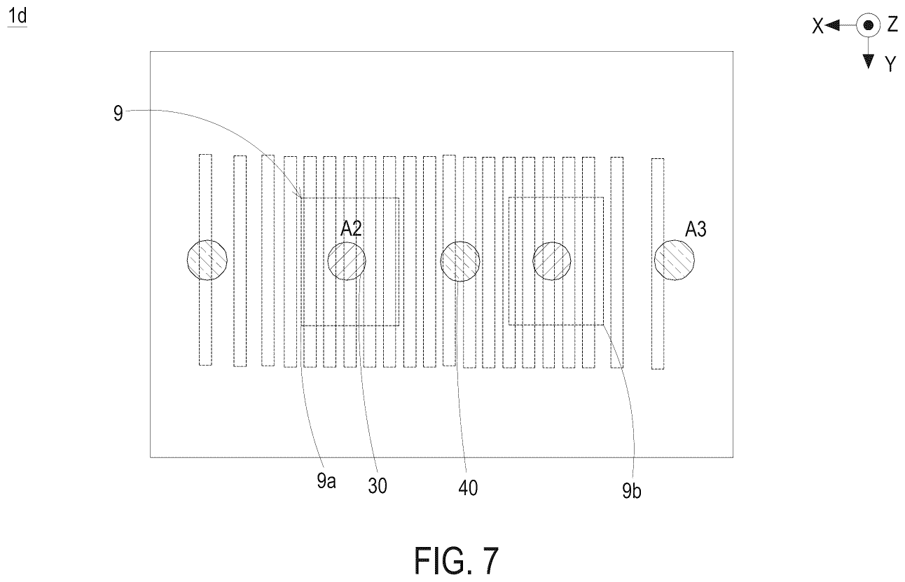

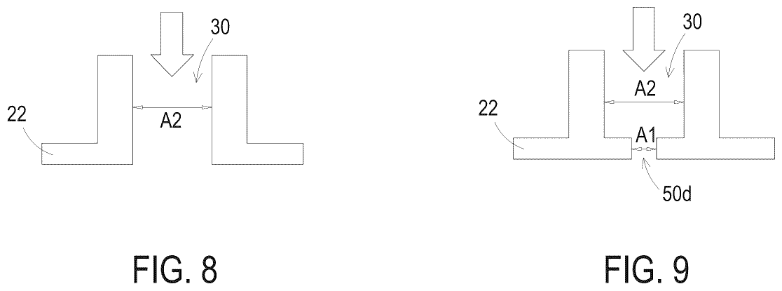

FIG. 6 is a schematic structural view illustrating a cold plate cooling device according to a fifth embodiment of the present disclosure. FIG. 7 is a top view illustrating the cold plate cooling device according to the fifth embodiment of the present disclosure. FIG. 8 to FIG. 11 show different exemplary structures having the jet module and the inlet integrally formed according to present disclosure. In the embodiment, the structures, elements and functions of the cold plate cooling device 1d are similar to those of the cold plate cooling device 1 of FIG. 1 and FIG. 2, and are not redundantly described herein. Please refer to FIG. 6 and FIG. 7. In the embodiment, the cold plate cooling device 1d includes a vapor chamber 10, a cooling chamber 20, an inlet 30, an outlet 40 and a jet module. Furthermore, the jet module is realized through the design of the inlet 30. In the embodiment, the cold plate cooling device 1d includes two inlets 30 and three outlets 40. The inlets 30 and the outlets 40 are disposed on the top cover 22 and spaced apart from each other. The positions of the two inlets 30 correspond to the heat sources 90a, 90b, respectively. That is, the inlets 30 are further included in a projection region of the heat sources 90a, 90b in view of the first direction (i.e., the reverse Z-axis direction). After flowing through the inlet 30 in the first flow direction F1 and flowing through the through-holes 50d, the coolant is directly guided to the heat sink fins 21 below.

Notably, in the embodiment, each inlet 30 and each outlet 40 may have the same pipe diameter, for example. Preferably but not exclusively, each inlet 30 is further connected to the cooling chamber 20 through a jet module. As shown in FIG. 6 and FIG. 9, the jet module includes a through-hole 50d, which is integrally formed and correspondingly connected with the inlet 30. That is, each inlet 30 is connected to the through-hole 50d of the jet module along the first direction (i.e., the reverse Z-axis direction) to form a step structure. The number of the inlets 30 is the same as the number of the through-holes 50d, which is two. Since the total through-hole area A1 formed by the two through-holes 50d is smaller than the total opening area A2 formed by the two inlets 30, the pressure of the coolant is increased when flowing through the through-hole 50d from the inlet 30. Thereby, two impingement flows J are generated to flow toward the plurality of heat sink fins 21 below directly. The heat dissipation performance of the vapor chamber 10 for the two heat sources 90a, 90 b is enhanced. After the completing heat exchange with the plurality of heat sink fins 21 in the cooling chamber 20, the coolant is discharged through the outlet 40 in the second flow direction F2. Thus, the heat is continuously and stably removed from the cold plate cooling device 1d.

Preferably but not exclusively, in the embodiment, the number of (two) inlet ports 30 is less than the number of (three) outlet ports 40. When the coolant directly flows toward the heat sink fins 21 in the cooling chamber 20 through the inlet 30 as shown in FIG. 8, a jet structure can be constructed through the difference in the area ratio of the total opening area A2 of the inlet 30 and the total through-hole area of the through-hole to create a jet effect. That is, the heat transfer effect of the heat sink fins 21 to the vapor chamber 10 is enhanced by the impingement flows J. Preferably but not exclusively, in other embodiments, the number of the inlets 30 and the number of the outlets 40 are the same, but the diameter of each outlet 40 is larger than the diameter of each inlet 30, so that the jet effect of the impingement flows J can also be achieved. Certainly, compared with the number difference or the area difference between the inlet 30 and the outlet 40, the inlet 30 and the through-hole 50d are connected and the jet module is integrally formed to further enhance the efficiency of the impingement flow J. The present disclosure is not limited thereto and not redundantly described hereafter.

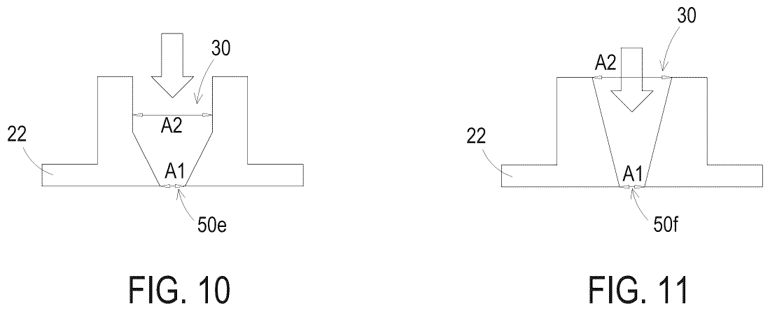

In an embodiment, the inlet 30 is extended along a first direction (i.e., the reverse Z-axis direction) and then gradually decreases in diameter to connect to the through-hole 50e, as shown in FIG. 10. When the coolant flows from the inlet 30 through the through-hole 50e, the pressure of the coolant is gradually increased to form the required impingement flow J directed to the heat sink fins 21 below. Thereby enhancing the heat dissipation performance of the vapor chamber 10 for the two heat sources 90a, 90b is enhanced. In addition, as the inlet 30 is extended along the first direction (i.e., the reverse Z-axis direction) and then gradually decreases in diameter to connect to the through-hole 50e, it also helps the coolant to flow through the inlet 30 and the through-hole 50e smoothly.

In another embodiment, the inlet 30 is directly connected to the through-hole 50f with a gradually decreasing diameter along the first direction (i.e., the reverse Z-axis direction), as shown in FIG. 11. It facilitates the coolant to flow through the inlet 30 and the through-hole 50e more smoothly to form the required impingement flow J. Certainly, in other embodiments, the through-holes 50d, 50e, 50f can be combined and changed according to the practical requirements and further connected with the inlet 30 to form the jet structure, which is integrally formed and directly disposed above the heat sources 90a, 90b. In addition, the number of the inlet 30 combined with the through-holes 50d, 50e, 50f and the number of the outlet 40 are also adjustable according to the practical requirements. In this way, the jet effect is achieved and the pressure drop of the coolant in the cooling chamber 20 is controlled. Moreover, the heat dissipation performance of the cold plate cooling device 1d having the vapor chamber 10 is optimized.

In summary, the present disclosure provides a cold plate cooling device with a vapor chamber. The vapor chamber is in contact with the chip package, so that the heat generated from different heat sources is quickly absorbed and then diffused through the phase change of the vapor chamber. In addition, the upper part of the vapor chamber is a liquid cooling plate, and a jet mechanism is introduced between multiple inlets and multiple outlets to enhance the heat transfer of the coolant, so that the heat generated from different heat sources is taken away evenly by the coolant enhanced by the jet module. In the present disclosure, the jet module is arranged between the inlet and the cooling chamber to form multiple impingement flows to dissipate heat from the cold plate below, so as to enhance the heat dissipation performance of the vapor chamber. The cooling chamber of the cold plate and vapor chamber are stacked up and down. The vapor chamber is thermally coupled to the chip package. Through the latent heat of phase change of the vapor chamber, the heat generated by the chip package can be absorbed and then diffused to the heat sink fins of the cold plate above. The heat sink fins are arranged in an open cooling chamber, and the coolant flows from the inlet to the outlet through the cooling chamber to take away the heat absorbed from the chip package. The jet module includes at least one through-hole of such as a partition plate disposed between the inlet and the cooling chamber. The partition plate further divides the cooling chamber into an upper and lower double-layer structure. The position of the through-hole is arranged and aligned correspondingly to the heat source. The coolant flowing through the inlet is transported from the upper buffer chamber to the lower cooling chamber through the through-hole on the partition plate. Since the total through-hole area of all through-holes on the partition plate is smaller than the total opening area of the inlet for the coolant, a jet effect can be created by the difference in the area ratio of the total opening area of the inlet to the total through-hole area of the through-holes. The coolant is evenly distributed through the through-holes and multi impingement flows are generated toward the plurality of heat sink fins in the lower cooling chamber for heat dissipation. Thereby, the heat dissipation performance of the vapor chamber for the chip package is enhanced. The numbers of inlets, through-holes and the outlets are adjustable according to the practical requirements and is not limited to one. The position of the through-hole on the partition plate can be adjusted to correspond to the position of the heat source and be misaligned from the inlet. The shape of the through-hole can be a circular aperture or an elongated aperture. Multiple outlets are disposed to reduce the pressure drop of the coolant flowing through the cooling chamber, so as to ensure that the jet module forms the impingement flow to improve the heat dissipation efficiency of the heat sink fins. On the other hand, the through-hole of the jet module and the inlet can be integrally formed into one piece and arranged above the heat source. By utilizing the difference in the ratio of the total opening area of the inlet and the total through-hole area of the through-hole, a jet structure is constructed to create a jet effect, so that the heat transfer effect of the heat sink fins to the vapor chamber is enhanced in an impingement-flow manner. The manner of constructing the jet structure adjacent to the inlet may be, for example, but not limited to, a step structure or a pipe with a gradually decreasing diameter. The number of the inlets integrated with the through-holes and the number of the outlets are adjustable according to the practical requirements. Furthermore, the pressure drop of the coolant in the cooling chamber can be controlled through the setting of the outlet. It also ensures that the jet module forms an impingement flow to improve the heat dissipation efficiency of the heat sink fins. The present disclosure includes the industrial applicability and the inventive steps.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A cold plate cooling device, comprising:
a vapor chamber comprising a top portion and a bottom portion, wherein the top portion and the bottom portion are arranged opposite to each other in a first direction, the bottom portion is thermally coupled to a heat source, and the top portion is thermally coupled to a plurality of heat sink fins;
a cooling chamber arranged on the top portion of the vapor chamber, wherein the plurality of heat sink fins are accommodated in the cooling chamber;
an inlet and an outlet in fluid communication with the cooling chamber, respectively, wherein a coolant enters the cooling chamber through the inlet, exchanges heat with the plurality of heat sink fins in the cooling chamber, and then is discharged through the outlet; and
a jet module comprising at least one through-hole arranged between the inlet and the cooling chamber, wherein the at least one through-hole has a total through-hole area, and the total through-hole area is smaller than a total opening area of the inlet, wherein when the coolant flows through the at least one through-hole, an impingement flow is generated toward the plurality of heat sink fins to dissipate heat from the vapor chamber.

2. The cold plate cooling device according to claim 1, wherein the at least one through-hole of the jet module is spatially corresponding to the heat source, and the at least one through-hole of the jet module is included in a projection region of the heat source in view of the first direction.

3. The cold plate cooling device according to claim 1, wherein the heat source comprises at least one pair of heat sources, and the at least one pair of heat sources are arranged along a second direction and thermally coupled to the bottom portion of the vapor chamber, wherein the second direction is perpendicular to the first direction.

4. The cold plate cooling device according to claim 1, further comprising a partition plate stacked along the first direction and arranged between the top portion of the vapor chamber and the inlet, wherein the jet module is disposed on the partition plate.

5. The cold plate cooling device according to claim 4, wherein the at least one through-hole and the inlet are misaligned in view of the first direction.

6. The cold plate cooling device according to claim 4, wherein the at least one through-hole comprises at least one pair of through-holes, which are arranged along a second direction and symmetrically disposed on two opposite sides of the inlet, wherein the second direction is perpendicular to the first direction.

7. The cold plate cooling device according to claim 4, wherein the at least one through-hole comprises at least one pair of circular apertures, which are located on two opposite sides of the inlet, respectively.

8. The cold plate cooling device according to claim 4, wherein the at least one through-hole comprises at least one pair of elongated apertures extended along a second direction and located at two opposite sides of the inlet, respectively, wherein the second direction is perpendicular to the first direction.

9. The cold plate cooling device according to claim 4, wherein the at least one through-hole is a circular aperture or an elongated aperture extended along a second direction, wherein the second direction is perpendicular to the first direction.

10. The cold plate cooling device according to claim 4, wherein a total opening area of the outlet is greater than the total through-hole area of the at least one through-hole.

11. The cold plate cooling device according to claim 4, wherein a buffer chamber is formed between the partition plate and the inlet, and the outlet comprises at least one pair of outlets, and the at least one pair of outlets are located at two opposite sides of the buffer chamber.

12. The cold plate cooling device according to claim 1, wherein the at least one through-hole and the inlet are integrally formed and correspondingly connected.

13. The cold plate cooling device according to claim 12, wherein the inlet is connected to the at least one through-hole of the jet module along the first direction to form a step structure.

14. The cold plate cooling device according to claim 12, wherein the inlet is connected to the at least one through-hole with a gradually decreasing diameter along the first direction.

15. The cold plate cooling device according to claim 12, wherein the inlet is included in a projection region of the heat source in view of the first direction.

16. The cold plate cooling device according to claim 1, wherein the heat source comprises at least one pair of heat sources, and the at least one pair of heat sources are arranged along a second direction and thermally coupled to the bottom portion of the vapor chamber, wherein the second direction is perpendicular to the first direction.

17. The cold plate cooling device according to claim 1, wherein the inlet comprises a plurality of inlets, the outlet comprises a plurality of outlets, and the number of the plurality of outlets is greater than or equal to the number of the plurality of inlets.

18. The cold plate cooling device according to claim 1, wherein the inlet comprises a plurality of inlets, the outlet comprises a plurality of outlets, and a total opening area of the plurality of outlets is greater than or equal to the total opening area of the plurality of inlets.

19. The cold plate cooling device according to claim 1, wherein the coolant flows through the inlet and the outlet parallel to the first direction.

20. The cold plate cooling device according to claim 1, wherein the heat source comprises a plurality of heat-generating chips packaged into one piece, and directly thermally coupled to the bottom portion of the vapor chamber.

21. The cold plate cooling device according to claim 1, wherein the top portion of the vapor chamber is integrally formed with the plurality of heat sink fins, and the plurality of heat sink fins are protruded from bottom to top.
